(19) United States
(12) Patent Application Publication
(10) Pub. No.: US 2014/0353709 A1
(43) Pub. Date: Dec. 4, 2014

(54) LIGHT EMITTING DIODE

(71) Applicants: POSCO LED Co., Ltd., Seongnam-si (KR); POSTECH Academy-Industry Foundation, Pohang-si (KR)

(72) Inventors: Jong Lam LEE, Pohang-si (KR); Sung Jun Kim, Seoul (KR); Yang Hee Song, Gwangmyeong-si (KR)

(73) Assignees: POSCO LED Co., Ltd., Seongnam-si (KR); POSTECH Academy-Industry Foundation, Pohang-si (KR)

(21) Appl. No.: 14/289,558

(22) Filed: May 28, 2014

(30) Foreign Application Priority Data
May 28, 2013 (KR) 10-2013-0060292

(51) Int. Cl. H01L 33/42; H01L 33/32

(52) U.S. Cl. CPC H01L 33/42; H01L 33/32
USPC 257/99

(57) ABSTRACT

Embodiments of the invention provide a gallium nitride-based light emitting diode including a transparent electrode, which includes a metal layer and a metal oxide layer. The light emitting diode includes a substrate, an n-type gallium nitride-based semiconductor layer disposed on the substrate, a p-type gallium nitride-based semiconductor layer disposed on the n-type gallium nitride-based semiconductor layer, an active layer interposed between the n-type gallium nitride-based semiconductor layer and the p-type gallium nitride-based semiconductor layer, and a transparent electrode disposed on the p-type gallium nitride-based semiconductor layer. Here, the transparent electrode has a multilayer structure including a first metal layer and a metal oxide layer sequentially stacked one above another, and impedance of the metal oxide layer matches impedance of an external environment at an interface between the metal oxide layer and the external environment.

### CROSS-REFERENCE TO RELATED APPLICATION

This application claims priority from and the benefit of Korean Patent Application No. 10-2013-0060292, filed on May 28, 2013, which is hereby incorporated by reference for all purposes as if fully set forth herein.

### BACKGROUND

1. Field

Exemplary embodiments of the present invention relate to light emitting diodes. More particularly, Exemplary embodiments of the present invention relate to a gallium nitride-based light emitting diode, which includes a transparent electrode including a metal layer and a metal oxide layer.

2. Discussion of the Background

A gallium nitride-based light emitting diode for white light sources has long lifespan, high directionality of light and operability at low voltage, does not require preheating time and complicated driving circuits, and is resistant to impact and vibration. Thus, the gallium nitride-based light emitting diode can realize a high quality lighting system in various ways and is expected to replace exiting light sources such as incandescent lamps, fluorescent lamps, and mercury lamps within 5 years.

In order for the gallium nitride-based light emitting diode to be used as a white light source by replacing existing mercury lamps or fluorescent lamps, it is necessary to secure excellent thermal stability and improved luminous efficacy while reducing fabricating costs. Improvement in luminous efficacy requires a transparent electrode having excellent capabilities.

Transparent electrodes are generally formed of indium tin oxide that has high transmittance and excellent electrical conductivity. However, ITO is prepared by a high energy process such as sputtering and E-beam evaporation, thereby causing damage to a semiconductor material under the transparent electrode. In addition, ITO is expensive due to indium which is an expensive material.

To address such problems in the art, Korean Patent Publication No. 2007-0069314A discloses a method of fabricating a transparent electrode, which has high light transmittance and excellent electrical conductivity based on an electrode structure formed by bonding Ag and an alkali metal enabling thermal deposition. In this case, however, the alkali metal is vulnerable to infiltration of water and oxygen, thereby causing deterioration in lifespan and device stability.

In addition, a p-type electrode pad formed on a p-type semiconductor layer is opaque. As a result, when the electrode pad has a large area, the quantity of light blocked by the electrode pad increases, thereby causing deterioration in light extraction efficiency. On the contrary, when the electrode pad has a narrow area, there can be a problem of current crowding due to non-uniform spreading of electrons injected from a large area device.

Therefore, studies have been continued to develop a transparent electrode that allows use of a small p-type electrode pad and has excellent capabilities.

The above information disclosed in this Background section is only for enhancement of understanding of the background of the invention and, therefore, it may contain information that does not constitute prior art.

### SUMMARY OF THE INVENTION

Exemplary embodiments of the present invention provide a gallium nitride-based light emitting diode having improved luminous efficacy.

Exemplary embodiments of the present invention provide a light emitting diode that has a transparent electrode structure capable of improving luminous efficacy.

Exemplary embodiments of the present invention provide a light emitting diode capable of improving lifespan and stability of devices.

Exemplary embodiments of the present invention provide a light emitting diode which allows reduction in size of a p-type electrode pad while preventing current crowding.

Additional features of the invention will be set forth in the description which follows, and in part will become apparent from the description, or may be learned from practice of the invention.

An exemplary embodiment of the present invention discloses a light emitting diode includes a substrate; an n-type gallium nitride-based semiconductor layer disposed on the substrate; a p-type gallium nitride-based semiconductor layer disposed on the n-type gallium nitride-based semiconductor layer; an active layer interposed between the n-type gallium nitride-based semiconductor layer and the p-type gallium nitride-based semiconductor layer; and a transparent electrode disposed on the p-type gallium nitride-based semiconductor layer. Here, the transparent electrode has a multilayer structure including a first metal layer and a metal oxide layer sequentially stacked one above another, and impedance of the metal oxide layer matches impedance of an external environment at an interface between the metal oxide layer and the external environment. With the matching structure, the light emitting diode can create zero reflection conditions, thereby improving luminous efficacy.

Herein, the term “external environment” may refer to a certain material or air adjoining a surface of the metal oxide layer to form an interface between the metal oxide layer and the material or air.

The first metal layer may include at least one of Ag, Au and Al.

The first metal layer may have a thickness from 1 nm to 100 nm.

The light emitting diode may further include a second metal layer between the first metal layer and the p-type semiconductor layer. Addition of the second metal layer can result in enhanced interlayer coupling force.

The second metal layer may include at least one of Ti, Ni and Cr.

The second metal layer may have a thickness from 0.1 nm to 100 nm.

In the transparent electrode of the light emitting diode according to the present invention, the metal oxide layer may include at least one of WOₓ, ZnOₓ, CaOₓ, TiOₓ, NiOₓ, CoOₓ, CeOₓ, SiOₓ, CuOₓ, AZO, and MoOₓ.

The metal oxide layer may have a thickness from 1 nm to 1000 nm.

The metal oxide layer may have a patterned upper surface.

The patterned upper surface may be formed by photolithography or nano imprinting.

The first metal layer and the metal oxide layer may be formed by thermal deposition.

The light emitting diode may further include a p-type electrode pad formed on some region of the first metal layer.

The p-type electrode pad may include at least one of Cr, Au, Ti, Al, Ni, Pd, Pt, or Ag.

The metal oxide layer may cover part of each of a side surface and an upper surface of the p-type electrode pad.

Exemplary embodiments of the present invention provide a light emitting diode, which includes a transparent electrode having low electrical resistance, high light transmittance, and allowing easy injection of charges into an active layer.

In addition, the light emitting diode including the transparent electrode according to the exemplary embodiments of the present invention can be easily fabricated by a process which can be easily incorporated into an existing fabricating process of a light emitting diode, thereby providing easy integration with the existing process and economic feasibility. Since the metal layer and the metal oxide layer of the transparent electrode can be formed by thermal deposition, the light emitting diode according to the exemplary embodiments of the invention does not require a high energy process, thereby preventing damage to a semiconductor layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a perspective view of a light emitting diode including a transparent electrode according to an exemplary embodiment of the present invention, showing a structure of the transparent electrode, and a graph depicting variation in admittance of each of a gallium nitride layer and layers included in the transparent electrode.

FIG. 2 is a graph depicting relationship between transmittance and thicknesses of a metal layer and a metal oxide layer constituting a transparent electrode according to an exemplary embodiment of the present invention.

FIG. 3 shows sectional views of light emitting diodes including transparent electrodes according to first and second exemplary embodiments of the present invention.

FIG. 4 shows graphs depicting relationship between transmittance and wavelength of light passing through the transparent electrodes according to the first and second exemplary embodiments of the present invention.

FIG. 5 shows graphs depicting relationship between luminous intensity and wavelength of light emitted from light emitting diodes including transparent electrodes according to an exemplary embodiment of the present invention.

FIG. 6 shows light emitting images and current-voltage graphs of light emitting diodes including transparent electrodes according to an exemplary embodiment of the present invention.

### DETAILED DESCRIPTION OF THE INVENTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art.

Further, it should be noted that the drawings are not to precise scale, and some of the dimensions, such as width, length, thickness, and the like, are exaggerated for clarity of description in the drawings. Like components are denoted by like reference numerals throughout the specification.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

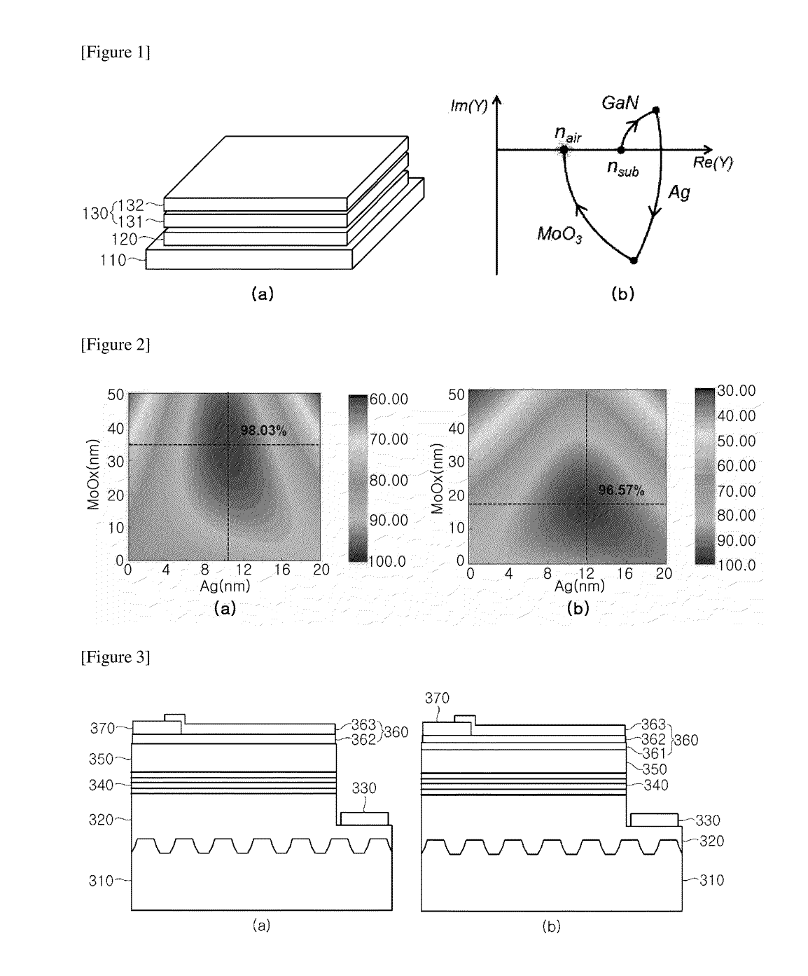

FIG. 1(a) is a perspective view of a gallium nitride-based light emitting diode including a transparent electrode according to an exemplary embodiment of the present invention, showing a structure of the transparent electrode. FIG. 1(b) is a graph depicting variation in admittance of each of a gallium nitride layer and layers included in the transparent electrode of the light emitting diode according to an exemplary embodiment of the present invention.

Referring to FIG. 1(a), a gallium nitride-based light emitting diode includes an active layer 110, a gallium nitride layer 120, and a transparent electrode 130. The transparent electrode 130 includes a metal layer 131 and a metal oxide layer 132.

The active layer 110 can output light having a predetermined wavelength through recombination of electrons and holes. The gallium nitride layer 120 is doped with p-type or n-type impurities to provide holes or electrons to the active layer 110.

The transparent electrode 130 has a multilayer structure which includes the metal layer 131 and the metal oxide layer 132. The metal layer 131 may include at least one of Ag, Au, Cu, Al, Ni and Pt, which have a low optical decay factor and exhibit excellent electrical conductivity. The metal oxide layer 132 may include at least one of Ta₂O₅, TiO₂, MoOₓ, NiOₓ, WOₓ, CuOₓ, ZrO₂, MgO, NiO, V₂O₅, MnO₂ and SnO₂, which have a low optical decay factor.

FIG. 1(b) is a graph depicting variation in admittance of each of layers constituting the light emitting diode including the transparent electrode according to an exemplary embodiment of the invention. The reciprocal of admittance is impedance, and there is a difference in impedance between different media having different indices of refraction. Impedance refers to the ratio of magnitude of an electrical field to magnitude of a magnetic field, and differs according to media through which light passes. When light passes through an interface between two media having different indices of refraction, reflection of light occurs due to a difference in impedance between the media. Impedance (or admittance) has a real part and an imaginary part, which can be calculated based on the indices of refraction of the media.

Referring to FIG. 1(b), admittance of the gallium nitride layer 120 varies along a GaN line, admittance of the metal layer 131 varies along an Ag line, and admittance of the metal oxide layer 132 varies along a MoO₃ line. Variation of each line can be obtained using the index of refraction of the corresponding medium. The admittance starting from the active layer 110 varies along the GaN line from an interface between the active layer 110 and the gallium nitride layer 120, and varies along the Ag line from an interface between the gallium nitride layer 120 and the metal layer 131 including Ag. Then, the admittance varies along the MoO₃ line from an interface between the metal layer 131 and the metal oxide layer 132 including MoO₃, and finally approaches admittance of air. Here, admittance at a certain point can be obtained using the values of the real axis (Re) and the imaginary axis (Im) at the certain point.

Referring to FIG. 1(a) and FIG. 1(b) again, in the light emitting diode including the transparent electrode according to the exemplary embodiment of the invention, the impedance (or admittance) of each of the gallium nitride layer 120, the metal layer 131 of the transparent electrode 130, and the metal oxide layer 132 of the transparent electrode 130 are changed such that impedance at an interface between the transparent electrode and air becomes identical to impedance of air, in order to achieve less reflection of light generated from the active layer 110. This condition is referred to as a zero reflection condition.

In addition, although air is illustrated as the external environment adjoining the transparent electrode in this exemplary embodiment of the invention, the present invention is not limited thereto. Accordingly, the metal oxide layer 132 of the transparent electrode 130 may form an interface with various external environments including air. For example, the external environment may be a molding section including an epoxy resin, a silicone resin, and the like.

$$\begin{matrix}ρ = \frac{{E}^{-}}{{E}^{+}} = \frac{{Y}_{air} - Y}{{Y}_{air} - Y} & Equation 1 \\ {\vert ρ \vert}^{2} = {\vert \frac{{Y}_{air} - Y}{{Y}_{air} + Y} \vert}^{2} & Equation 2\end{matrix}$$

In Equation 1, ρ is a reflection coefficient, E⁻ is the magnitude of energy emitted from the light emitting diode, E⁺ is the magnitude of energy entering the light emitting diode, Yₐᵢᵣ is admittance of air, and Y is admittance at an interface between a component and air. In Equation 2, the square of an absolute value of the reflection coefficient ρ is reflectivity.

Referring to Equations 1 and 2, in order for the transparent electrode to have a reflectivity of 0, that is, zero reflection condition, Yₐᵢᵣ must be equal to Y. This condition is referred to as admittance (or impedance) matching. Accordingly, when the transparent electrode has a zero reflection condition, light can be completely discharged from the light emitting diode instead of being reflected inside the light emitting diode, thereby improving luminous efficacy of the light emitting diode. Conversely, when there is a large difference between Yₐᵢᵣ and Y, internal reflectivity of the light emitting diode increases, thereby causing decrease in transmittance and luminous efficacy of the light emitting diode. Here, it should be understood that impedance matching is not limited to an ideal state in which reflectivity is 0 and includes the case where the transparent electrode has a reflectivity of at least 10% or less.

The light emitting diode according to the invention allows minimized reflection of light generated from the active layer 110 by the media, and thus can minimize reduction of transmittance, thereby improving luminous efficacy of the light emitting diode.

FIG. 2 is a graph depicting relationship between transmittance and thicknesses of the metal layer and the metal oxide layer constituting the transparent electrode according to exemplary embodiments of the present invention. Referring to FIG. 2, the metal layer 131 is formed of Ag and the metal oxide layer 132 is formed of MoO₃. The graph shows transmittance of the transparent electrode depending upon the thicknesses of Ag and MoO₃ in plan view. At a wavelength of 435 nm in FIG. 2(a), it can be seen that, when the Ag layer has a thickness of about 9.2 nm and the MoO₃ layer has a thickness of about 30 nm, the transparent electrode has a transmittance of 98.03%. At a wavelength of 450 nm in FIG. 2(b), it can be seen that, when the Ag layer has a thickness of about 12 nm and the MoO₃ layer has a thickness of about 17 nm, the transparent electrode has a transmittance of 96.57%. In other words, since impedance also varies upon variation in the thicknesses of the metal layer and the metal oxide layer, it is possible to form a transparent electrode having high transmittance by setting an optimal thickness of the transparent electrode.

FIG. 3 shows sectional views of light emitting diodes including transparent electrodes according to first and second exemplary embodiments of the present invention. FIG. 3(a) is a sectional view of the light emitting diode including the transparent electrode according to the first exemplary embodiment of the invention. FIG. 3(b) is a sectional view of the light emitting diode including the transparent electrode according to the first exemplary embodiment of the invention.

Referring to the first exemplary embodiment shown in FIG. 3(a), the light emitting diode includes a substrate 310, an n-type gallium nitride-based semiconductor layer 320 disposed on the substrate, an n-type electrode pad 330, an active layer 340, a p-type gallium nitride-based semiconductor layer 350, a transparent electrode 360, and a p-type electrode pad 370. The transparent electrode 360 includes a first metal layer 362 and a metal oxide layer 363.

The substrate 310 may be formed of aluminum oxide (Al₂O₃). The substrate 310 may have a heat dissipation pattern, which may have a convex-concave shape, a sawtooth shape, a semi-spherical shape, and a combination thereof, formed on one surface thereof to improve dissipation of heat generated from the light emitting diode.

The n-type gallium nitride-based semiconductor layer 320 is a layer that supplies electrons to the active layer, and may be formed of a gallium nitride-based compound semiconductor, such as GaN AN, InGaN, AlGaN, AlInGaN, and the like.

The n-type electrode pad 330 is formed on an exposed surface of the n-type gallium nitride-based semiconductor layer 320 and may be formed by a lift-off process. The n-type electrode serves as a connection part for a power source and may be formed of Ag, Al, and the like.

The active layer 340 may be disposed in some region on the n-type gallium nitride-based semiconductor layer 320. In the active layer 340, electrons supplied from the n-type gallium nitride-based semiconductor layer 320 recombine with holes supplied from the p-type gallium nitride-based semiconductor layer 350 to generate light having a predetermined wavelength. The active layer 340 may be formed as a multilayer semiconductor film, which has a single or multi-quantum well structure formed by alternately stacking well layers and barrier layers. Since the wavelength of light generated from the active layer 340 varies according to the material of the active layer, the active layer may be formed of a suitable material depending upon desired output wavelengths.

The p-type gallium nitride-based semiconductor layer 350 is a layer that supplies holes to the active layer, and may be formed of the gallium nitride-based compound semiconductor, such as GaN, AN, InGaN, AlGaN, AlInGaN, and the like.

The transparent electrode 360 has a multilayer structure including the first metal layer 362 and the metal oxide layer 363 disposed on the first metal layer 362. The first metal layer 362 may include at least one of Ag, Au and Al. The first metal layer 362 may have a thickness from 1 nm to 100 nm. If the thickness of the first metal layer 362 is less than 1 nm, current spreading from the p-type electrode 370 to the p-type gallium nitride-based semiconductor layer 350 becomes difficult, and if the thickness of the first metal layer 362 is greater than 100 nm, the first metal layer 362 absorbs light emitted from the active layer, thereby causing reduction in transmittance. The metal oxide layer 363 may include at least one of WOₓ, ZnOₓ, CaOₓ, TiOₓ, NiOₓ, CoOₓ, CeOₓ, SiOₓ, CuOₓ, AZO, and MoOₓ. The metal oxide layer 363 may have a thickness from 1 μm to 1 nm. If the thickness of the metal oxide layer 363 is less than 1 μm, it is difficult to enhance transmittance through zero reflection, and if the thickness of the metal oxide layer exceeds 1 nm, the metal oxide layer absorbs light emitted from the active layer, thereby causing reduction in transmittance. An upper surface of the metal oxide layer 363 may be subjected to patterning through photolithography or nano-imprinting. The light emitting diode may have improved light extraction efficiency by patterning the upper surface of the metal oxide layer.

The p-type electrode pad 370 serves to allow inflow of electric current into the light emitting diode therethrough, and may include at least one of Cr, Au, Ti, Al, Ni, Pd, Pt and Ag. The p-type electrode pad 370 may be formed on the first metal layer 362 by a lift-off process. Each of an upper surface and a side surface of the p-type electrode pad 370 may be partially covered by the metal oxide layer 363. This structure can improve electrical characteristics and bonding force of the p-type electrode pad 370. Since current crowding can be prevented by the transparent electrode 360, the p-type electrode pad 370 can be formed in a narrow area. Thus, the light emitting diode according to the present invention has improved luminous efficacy.

Referring to FIG. 3(b), the light emitting diode according to this exemplary embodiment has a similar structure to the light emitting diode of FIG. 3(a), and further includes a second metal layer between the p-type semiconductor layer and the first metal layer. Specifically, in the second exemplary embodiment of FIG. 3(b), the transparent electrode 360 includes a first metal layer 362, a metal oxide layer 363, and a second metal layer 361.

The second metal layer 361 includes at least one of Ti, Ni and Cr. The second metal layer 361 may be disposed between the first metal layer 362 and the p-type gallium nitride-based semiconductor layer 350 and enhance coupling force between the thin layers. The second metal layer 361 may have a thickness from 0.1 nm to 100 nm. If the thickness of the second metal layer 361 exceeds 100 nm, overall transmittance of the transparent electrode 360 can be reduced, and if the thickness of the second metal layer is less than 0.1 nm, there can be a problem of reduction in coupling force.

The light emitting diode having the structure as described above may be fabricated by the following process. First, a gallium nitride semiconductor layer is formed on a sapphire substrate by metal organic chemical vapor deposition (MOCVD). The gallium nitride semiconductor layer is dipped in a sulfuric acid solution (sulfuric acid:deionized water=1:1) for 10 minutes, followed by washing with deionized water and drying with nitrogen. Then, a mesa pattern dividing an n-type gallium nitride-based semiconductor layer and a p-type gallium nitride-based semiconductor layer is formed by photolithography, followed by dry etching using a photoresist to expose the n-type gallium nitride-based semiconductor layer.

After the pattern is formed on the p-type gallium nitride-based semiconductor by photolithography, a transparent electrode is formed on the pattern by thermal deposition. The transparent electrode is formed by depositing Ni layer (second metal layer) to a thickness of 0.5 nm in a vacuum of 1×10⁻⁶ Torr, followed by depositing Ag layer (first metal layer) to a thickness of 10 nm. At this time, when the deposition rate of Ag layer increases from 0.1 nm/s to 1 nm/s, it is possible to maintain low surface resistance even in a metal layer having a small thickness. A low deposition rate of metal can cause the metal layer to be formed in an island shape instead of a thin film shape, whereby surface resonance occurs between the gallium nitride layer and the metal layer, thereby causing reduction in transmittance of the transparent electrode. Although a high deposition rate of metal can form the metal layer in a thin film shape, there is a problem of deterioration in transmittance of the transparent electrode due to difficulty in adjustment of the thickness of the metal layer transparent electrode. Further, when 3 wt % of Mg or Ti is included in the Ag layer (first metal layer), it is possible to provide low surface resistance even in a metal layer having a small thickness. With the lift-off process and photolithography, a p-type electrode pattern may be formed on the metal layer of the transparent electrode, and an n-type electrode pattern may be formed on the n-type gallium nitride-based semiconductor. The p-type and n-type electrode pads are deposited on the p-type and n-type electrode patterns, respectively. Then, MoO₃ layer is deposited to a thickness of 35 nm to form the metal oxide layer on the metal layer of the transparent electrode by photolithography, thereby completing a light emitting diode.

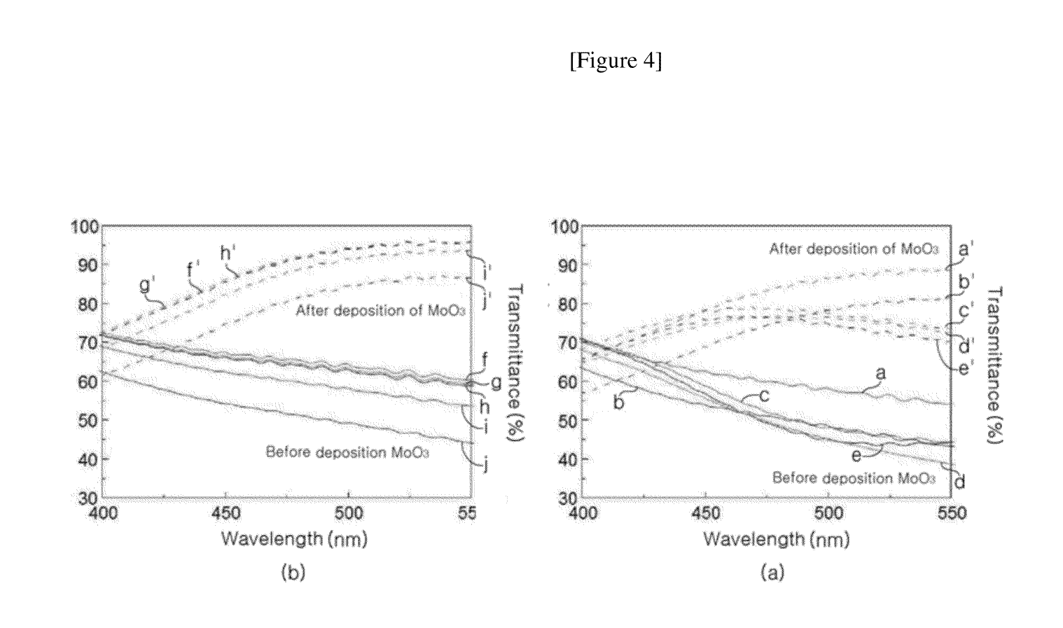

FIG. 4 shows graphs depicting relationship between transmittance and wavelength of light passing through the transparent electrodes according to the first and second exemplary embodiments of the present invention. FIG. 4(a) is a graph depicting relationship between transmittance and wavelength of light passing through the transparent electrode according to the first exemplary embodiment. FIG. 4(b) is a graph depicting relationship between transmittance and wavelength of light passing through the transparent electrode according to the second exemplary embodiment.

Referring to FIG. 4(a), lines a, b, c, d and e indicate transmittance of a transparent electrode including an Ag layer (first metal layer), before deposition of MoO₃ according to wavelength of light passing through the transparent electrode.

Specifically, line a indicates transmittance of the transparent electrode in which Ag layer is deposited at a rate of 5 A/s; line b indicates transmittance of the transparent electrode in which Ag layer is deposited at a rate of 10 A/s; line c indicates transmittance of the transparent electrode in which the Ag layer contains 3 wt % of Ti; line d indicates transmittance of the transparent electrode in which the Ag layer contains 3 wt % of Mg; and line e indicates transmittance of the transparent electrode in which Ag is deposited at a rate of 1 A/s.

Lines a′, b′, c′, d′ and e′ indicate transmittance of a transparent electrode including an Ag layer (first metal layer) and a MoO₃ layer (metal oxide layer) after deposition of MoO₃ according to wavelength of light passing through the transparent electrode. Specifically, line a′ indicates transmittance of the transparent electrode in which Ag layer is deposited at a rate of 5 A/s; line b′ indicates transmittance of the transparent electrode in which Ag layer is deposited at a rate of 10 A/s; line c′ indicates transmittance of the transparent electrode in which the Ag layer contains 3 wt % of Ti; line d′ indicates transmittance of the transparent electrode in which the Ag layer contains 3 wt % of Mg; and line e′ indicates transmittance of the transparent electrode in which the Ag layer is deposited at a rate of 1 A/s. That is, it can be seen that, the transparent electrode has improved transmittance when the metal oxide layer is formed on the metal layer.

FIG. 4(b) shows relationship between transmittance and wavelength depending upon deposition of the metal oxide layer when the transparent electrode includes two metal layers. One of the metal layers may be formed of Ag and the other metal layer may be formed of Ni.

Lines f, g, h, i and j indicate transmittance of the transparent electrode including the Ag layer (first metal layer) and the Ni layer (second metal layer) before deposition of MoO₃ according to wavelength of light passing through the transparent electrode.

Specifically, line f indicates transmittance of the transparent electrode including the Ag layer containing 3 wt % of Ti and the Ni layer; line g indicates transmittance of the transparent electrode including the Ag layer containing 3 wt % of Mg and the Ni layer; line h indicates transmittance of the transparent electrode in which the Ag layer and the Ni layer are deposited at a rate of 1 A/s; line i indicates transmittance of the transparent electrode in which the Ag layer and the Ni layer are deposited at a rate of 5 A/s; line j indicates transmittance of the transparent electrode in which the Ag layer and the Ni layer are deposited at a rate of 10 A/s.

Lines f′, g′, h′, i′ and j′ indicate transmittance of a transparent electrode including an Ag layer (first metal layer), a Ni layer (second metal layer) and a MoO₃ layer (metal oxide layer) after deposition of MoO₃, according to wavelength of light passing through the transparent electrode.

Specifically, line f′ indicates transmittance of the transparent electrode including the Ag layer containing 3 wt % of Ti and the Ni layer; line g′ indicates transmittance of the transparent electrode including the Ag layer containing 3 wt % of Mg and the Ni layer; line h′ indicates transmittance of the transparent electrode in which the Ag layer and the Ni layer are deposited at a rate of 1 A/s; line i′ indicates transmittance of the transparent electrode in which the Ag layer and the Ni layer are deposited at a rate of 5 A/s; line j′ indicates transmittance of the transparent electrode in which the Ag layer and the Ni layer are deposited at a rate of 10 A/s. From the results, it can also be seen that the transparent electrode has improved transmittance when the metal oxide layer is formed on the metal layer.

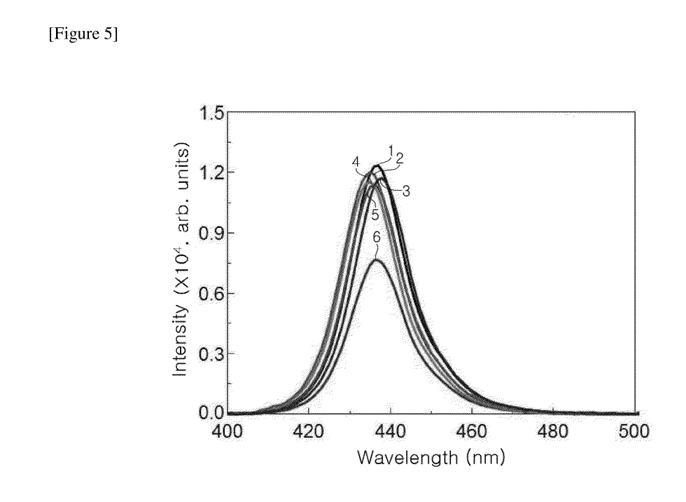

FIG. 5 shows graphs depicting relationship between luminous intensity and wavelength of light emitted from light emitting diodes including transparent electrodes according to exemplary embodiments of the present invention. Referring to FIG. 5, lines 1 to 6 form graphs depicting relationship between luminous intensity and wavelength of light emitted from the light emitting diode in which the transparent electrode is formed of ITO; in which the transparent electrode is formed of Ni/Ag and the Ag layer contains 3 wt % of Mg; in which the transparent electrode is formed of Ni/Ag and the Ag layer contains 3 wt % of Ti; in which the transparent electrode is formed of Ni/Ag at a deposition rate of 10 A/s; in which the transparent electrode is formed of Ni/Ag at deposition rate of 5 A/s; and in which the transparent electrode is formed of Ni/Ag at deposition rate of 1 A/s, respectively.

That is, it can be seen that the existing transparent electrode formed of ITO and the transparent electrode including the Ni and Ag layers exhibit similar luminous intensity except for line 6. Accordingly, it can be seen that the configuration of the transparent electrode according to an exemplary embodiment of the present invention can replace the existing transparent electrode.

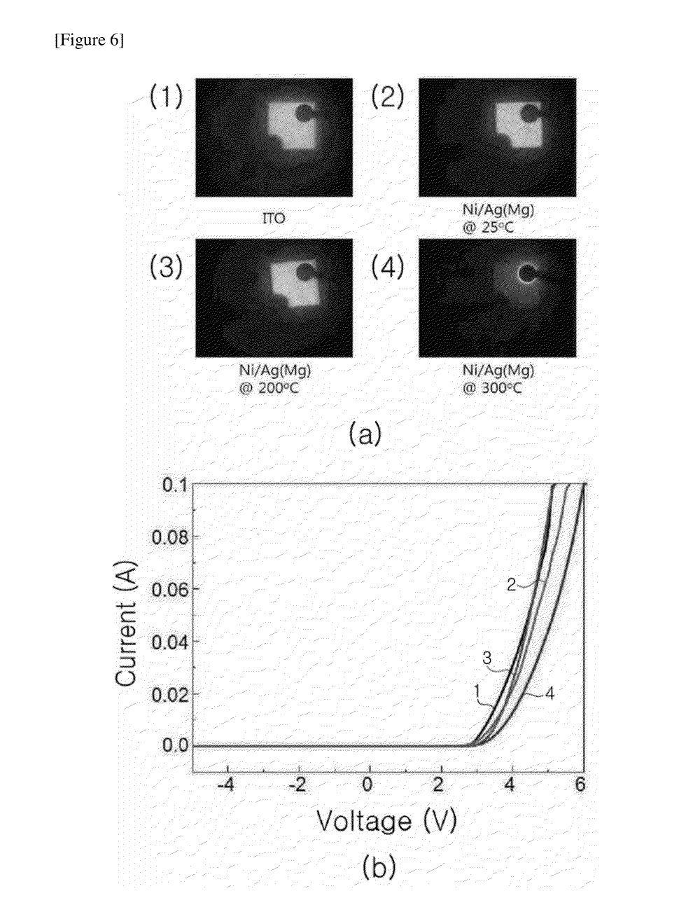

FIG. 6 shows light emitting images and current-voltage graphs of light emitting diodes including transparent electrodes according to exemplary embodiments of the present invention. FIG. 6(a) shows light emitting images of the light emitting diodes including the transparent electrodes according to the exemplary embodiments of the present invention. FIG. 6(b) shows current-voltage graphs of the light emitting diodes including the transparent electrodes according to the exemplary embodiments of the present invention.

Referring to FIG. 6(a), (1) is a light emitting image of the light emitting diode in which the transparent electrode is formed of ITO as in the art, (2) is a light emitting image of the light emitting diode in which the transparent electrode is formed of Ni and Ag containing 3 wt % of Mg and is formed at 25° C., (3) is a light emitting image of the light emitting diode in which the transparent electrode is formed of Ni and Ag containing 3 wt % of Mg and is subjected to heat treatment at 200° C., and (4) is a light emitting image of the light emitting diode in which the transparent electrode is formed of Ni and Ag containing 3 wt % of Mg and is subjected to heat treatment at 300° C. Comparing the light emitting images, it can be seen that the light emitting diodes have similar luminous intensity except for (4) of FIG. 6(a).

Referring to FIG. 6(b), line 1 forms a current-voltage graph of the light emitting diode of FIG. 6(a)(1), line 2 forms a current-voltage graph of the light emitting diode of FIG. 6(a)(3), line 3 forms a current-voltage graph of the light emitting diode of FIG. 6(a)(4), and line 4 forms a current-voltage graph of the light emitting diode of FIG. 6(a)(2). From these graphs, it can be seen that the operating voltage of the light emitting diode including the Ni/Ag transparent electrode can be lowered to a level similar to that of the light emitting diode including the ITO transparent electrode through suitable heat treatment.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A light emitting diode comprising:
a substrate;
an n-type gallium nitride-based semiconductor layer disposed on the substrate;
a p-type gallium nitride-based semiconductor layer disposed on the n-type gallium nitride-based semiconductor layer;
an active layer interposed between the n-type gallium nitride-based semiconductor layer and the p-type gallium nitride-based semiconductor layer; and
a transparent electrode disposed on the p-type gallium nitride-based semiconductor layer,
wherein the transparent electrode has a multilayer structure including a first metal layer and a metal oxide layer sequentially stacked one above another, and impedance of the metal oxide layer matches impedance of an external environment at an interface between the metal oxide layer and the external environment.

2. The light emitting diode of claim 1, wherein the first metal layer comprises at least one of Ag, Au and Al.

3. The light emitting diode of claim 1, wherein the first metal layer has a thickness from 1 nm to 100 nm.

4. The light emitting diode of claim 1, further comprising: a second metal layer between the first metal layer and the p-type semiconductor layer.

5. The light emitting diode of claim 4, wherein the second metal layer comprises at least one of Ti, Ni and Cr.

6. The light emitting diode of claim 4, wherein the second metal layer has a thickness from 0.1 nm to 100 nm.

7. The light emitting diode of claim 1, wherein the metal oxide layer comprises at least one of WOₓ, ZnOₓ, CaOₓ, TiOₓ, NiOₓ, CoOₓ, CeOₓ, SiOₓ, CuOₓ, AZO and MoOₓ.

8. The light emitting diode of claim 1, wherein the metal oxide layer has a thickness from 1 nm to 1000 nm.

9. The light emitting diode of claim 1, wherein the metal oxide layer has a patterned upper surface.

10. The light emitting diode of claim 7, wherein the patterned upper surface is formed by photolithography or nano imprinting.

11. The light emitting diode of claim 1, wherein the first metal layer and the metal oxide layer are formed by thermal deposition.

12. The light emitting diode of claim 1, further comprising: a p-type electrode pad on some region of the first metal layer.

13. The light emitting diode of claim 12, wherein the p-type electrode pad comprises at least one of Cr, Au, Ti, Al, Ni, Pd, Pt or Ag.

14. The light emitting diode of claim 12, wherein the metal oxide layer covers part of each of a side surface and an upper surface of the p-type electrode pad.
